(19) United States
(12) Patent Application Publication
(10) Pub. No.: US 2025/0238569 A1
(43) Pub. Date: Jul. 24, 2025

(54) Method for Predicting Machined Surface Roughness of Parts Based on Attention and Transfer Learning

(71) Applicant: Zhejiang University, Hangzhou (CN)

(72) Inventors: Zhenyu LIU, Hangzhou (CN); Chan QIU, Hangzhou (CN); Guodong SA, Hangzhou (CN); Jianrong TAN, Hangzhou (CN); Boyang CAI, Hangzhou (CN); Kaiyi ZHU, Hangzhou (CN)

(21) Appl. No.: 18/699,256

(22) PCT Filed: Dec. 19, 2023
(86) PCT No.: PCT/CN2023/139760

§ 371 Date: Apr. 5, 2024

(30) Foreign Application Priority Data
Sep. 6, 2023 (CN) 202311144250.8

(51) Int. Cl. G06F 30/17; G06F 30/27

(52) U.S. Cl. CPC G06F 30/17; G06F 30/27

(57) ABSTRACT

A method for predicting machined surface roughness of parts based on attention and transfer learning is provided. The method includes the following steps: first, acquiring key physical signals that affect evolution of machined surface roughness of parts of a computer numerical control machine tool and constructing a signal feature matrix; inputting the respective signal feature matrixes into a machined surface roughness prediction model for training, and obtaining a trained machined surface roughness prediction model; constructing a machine tool single-index degradation model, determining a degradation trend of the current computer numerical control machine tool, and in different degradation stages of the degradation trend, performing network model transferring on the machined surface roughness prediction models by using a transferring method separately, so as to obtain the machined surface roughness prediction models in different degradation stages, and realize the machined surface roughness prediction in different degradation stages.

### TECHNICAL FIELD

The present disclosure relates to a method for predicting roughness of a numerical control machined surface of parts, in particular to a method for predicting roughness of a numerical control machined surface of parts based on attention mechanism and transfer learning.

### BACKGROUND

Numerical control machining has a great impact on assembly accuracy, fatigue strength and corrosion resistance of parts, so that the machining accuracy of a machine tool is an important index to evaluate the performance of the machine tool. In previous machining operations, in order to ensure the machining quality, it is necessary to measure the surface roughness of parts off-line. Due to the problems such as low efficiency and the high measurement cost in the off-line measurement method of the machining accuracy, the machining efficiency is low. Therefore, the prediction method of the numerical control machining accuracy of parts is very important to improve the machining quality and the production efficiency of parts.

The roughness prediction methods mainly include a roughness prediction method based on traditional data regression and a roughness prediction method through artificial intelligence. Although a method of predicting machining accuracy based on traditional data regression can obtain an explicit model of predicting machining accuracy, when the experimental conditions change, a regression equation needs to be re-established. Therefore, the model of predicting machining accuracy based on traditional data regression has poor robustness and is not universally applicable to predict machining accuracy of a grinding machine. Some roughness prediction methods based on artificial intelligence do not take into account the time-varying features of input signals, so that the robustness of the prediction model is poor.

At present, according to the multi-source input data signal features of the prediction model, some neural network models directly output the results after convolution operation and other processing through the fully connected layer for predicting the type. However, since the dimension of sensor data signals is large and different types of signals have different abilities to characterize features, there is a lack of analysis and fusion processing of signal features. In addition, in a case that the numerical control machine tool is in service for a long time, due to the wear and aging of various parts, the processing is affected, thereby reducing the accuracy of the precision prediction model. Therefore, the performance of the network prediction models built in most studies will degrade over time.

### SUMMARY

In order to solve the problems existing in the background, the present disclosure provides a method for predicting roughness of a numerical control machined surface of parts based on attention mechanism and transfer learning. The method of the present disclosure can overcome the shortcomings of the existing method above, realize the learning and fusion of the signal features of numerical control machining of a plurality of parts by the prediction model, and solve the problem of performance degradation of the neural network prediction model in a long time span.

In order to achieve the above-mentioned purpose, the technical solution of the present disclosure is as follows:
S1, acquiring key physical signals that affect evolution of machined surface roughness of parts from a computer numerical control machine tool;
S2, obtaining corresponding features, after performing a preprocessing and a feature extraction on respective key physical signals, and constructing corresponding signal feature matrixes according to the features corresponding to respective key physical signals;
S3, inputting respective signal feature matrixes into a machined surface roughness prediction model for training, and obtaining a trained machined surface roughness prediction model;
S4, constructing a machine tool single-index degradation model according to measured degradation data of the computer numerical control machine tool, determining a degradation trend of a current computer numerical control machine tool by using the machine tool single-index degradation model, and in different degradation stages of the degradation trend, performing network model transferring on the trained machined surface roughness prediction model by using a transferring method according to the key physical signals of respective degradation stages, so as to obtain machined surface roughness prediction models in different degradation stages; and
S5, determining a degradation stage of the current computer numerical control machine tool according to the machine tool single-index degradation model, and selecting a machined surface roughness prediction model of a current degradation stage, so as to obtain a corresponding surface roughness prediction result.

In the S2, a feature corresponding to each of key physical signals includes a time domain signal feature and a frequency domain signal feature.

The machined surface roughness prediction model includes a convolution layer, a memory network layer, a random dropout layer, a fully connected layer, a sub-path random dropout block, an improved SE Context Gating attention mechanism block and a classification module;
each of signal feature matrixes is input into the corresponding convolution layer, an output of each convolution layer is input into the classification module after passing through the corresponding first fully connected layer and the sub-path random dropout block, outputs of all convolution layers are input into the random dropout layer after passing through respective memory network layers, the random dropout layer is connected with the improved SE Context Gating attention mechanism block through a second fully connected layer, the improved SE Context Gating attention mechanism block is connected with the classification module, and the classification module outputs a prediction result of machined surface roughness.

The improved SE Context Gating attention mechanism block includes a third fully connected layer and an activation layer, an input of the improved SE Context Gating attention mechanism block is used as an input of the third fully connected layer, the third fully connected layer is connected with the activation layer, a fused feature after performing feature fusion on an the output of the activation layer and the input of the improved SE Context Gating attention mechanism block is used as an output of the improved SE Context Gating attention mechanism block.

In the S4, a formula of the machine tool single-index degradation model is as follows:

$$Y ( t ) = {m}_{t} \cdot exp ( {n}_{t} , t ) + {ε}_{t}$$

where Y(t) is a machine tool degradation performance at time t, mₜ is an initial machine tool performance level at time t, nₜ indicates a machine tool degradation rate at time t, and εₜ is Gaussian white noise.

In the S4, according to the measured degradation data of the current computer numerical control machine tool, a Monte Carlo particle filtering method is used to perform model update on a single-index degradation observation equation to obtain the machine tool single-index degradation model.

In the present disclosure, convolution compression and time sequence feature extraction are performed on numerical control machined signals of parts through a method for predicting roughness of the numerical control machined surface of parts based on attention mechanism and transfer learning; an attention mechanism is used to learn and fuse a plurality of signal features; a state equation is constructed by using an index degradation model, and the degradation trend of the machine tool is calculated by a particle filtering algorithm; a transfer learning method is used to improve the prediction performance of the prediction model; thereby realizing the high-quality prediction of roughness of the numerical control machined surface of parts.

Compared with the prior art and the method, the present disclosure has the following beneficial effects.

In the present disclosure, a SE Context Gating mechanism is fused into model training, and the spliced features are sent to SE Context Gating to obtain a fusion result of a plurality of features. By adding the fused features and the original features, it is possible to ensure that the original information of the original features is retained and that the information after the original features are fused is helpful for the prediction results, so that the model can learn more feature information.

In the present disclosure, the fused features and a plurality of signal features input are fused again. At the same time, DropPath is used to randomly discard some samples in each group of batchsizes that are fused into the network every time, so as to improve the robustness of the model.

In the present disclosure, the degradation trend of machine tool is calculated through the particle filtering algorithm, and the accuracy of the built neural network prediction model is improved based on a transfer learning method of the network layered freezing, so that the prediction model is suitable for predicting the machining accuracy of machine tool in multiple situations, thereby solving the problem that the prediction performance of the neural network degrades when the machine tool is in long-term service.

To sum up, the present disclosure achieves multi-signal feature fusion and prediction model transferring suitable for computer numerical control machine tool, thereby realizing the prediction of roughness of the numerical control machined surface of parts.

### BRIEF DESCRIPTION OF THE DRAWINGS

FIG. 1 is a flowchart of a method according to the present disclosure.

FIG. 2 is a structural schematic diagram of a prediction model during implementation of the method according to the present disclosure.

FIG. 3 is a structural schematic diagram of an improved attention mechanism during the implementation of the method according to the present disclosure.

FIG. 4 is a flowchart of a particle filtering for solving a degradation trend during the implementation according to the present disclosure.

FIG. 5 is a schematic diagram of a transfer learning process during the implementation according to the present disclosure.

### DETAILED DESCRIPTION OF THE EMBODIMENTS

The present disclosure will be further explained below in conjunction with the drawings and specific examples.

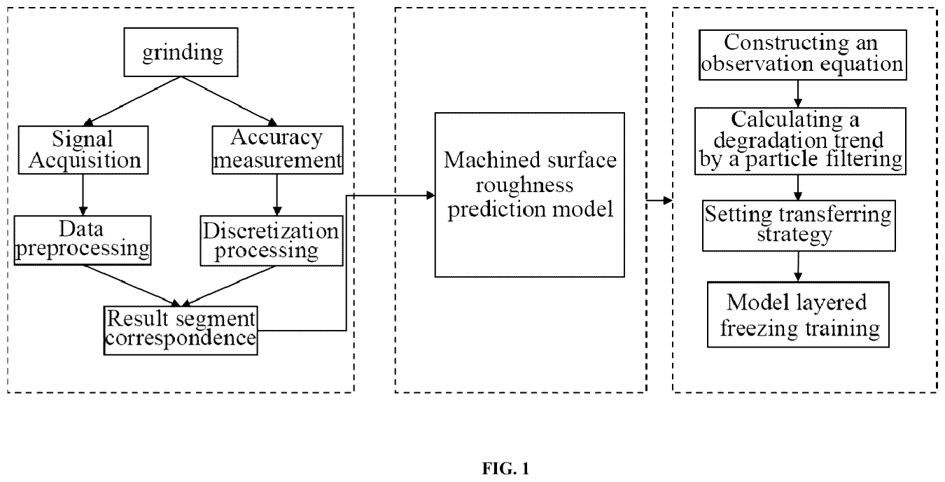

The embodiment of the present disclosure uses a surface forming grinding machine as an example for illustration, as shown in FIG. 1, which specifically includes the following steps S1 to S5.

In step S1, key physical signals that affect evolution of machined surface roughness of parts from a computer numerical control machine tool are acquired, where the key physical signals include temperature signals and vibration signals during machining process.

In this embodiment, the evolution features of numerical control machined surface roughness of parts are analyzed. With the help of an OPC UA (Open Production Control and Unified Architecture) protocol and various sensors, an experimental environment platform is built based on the existing computer numerical control machine tool in the actual factory production workshop, and a temperature signal, a vibration signal and a motor power signal during the machining process are acquired. The cutting tool wear is one of the important factors in the machine tool machining process, which will directly affect the machined surface roughness. When the cutting tool is worn, the increase of a cutting force leads to the change of motor power. The vibration at the grinding head includes grinding wheel vibration and motor vibration. Because the workpiece is fixed on a workpiece table through the fixture during machining, the vibration features of the workpiece table also affect the machining accuracy of the parts. The front and rear bearings of the spindle are connected to the temperature sensors arranged on the outer side. In addition, it is necessary to measure the operating environment temperature and the coolant temperature of the machine tool. In the process of machining, the deformation and displacement of the workpiece table will also affect the grinding results, and thus the vibration signals of the workpiece table are mainly acquired.

In step S2, after performing a preprocessing and a feature extraction on each respective key physical signals, corresponding features are obtained, and corresponding signal feature matrixes are constructed according to the features corresponding to respective key physical signals and are used as the input of a prediction model, where each type of key physical signal obtains a signal feature matrix correspondingly. Affected by the factors such as environment, there are some problems such as noise, data missing and data redundancy in the acquired original data. Therefore, in this embodiment, a series of operations such as denoising, deduplication, and data completion are performed on the acquired signal data. According to the acquired distribution of surface roughness data, the majority of samples have roughness below 0.5 μm, while a small number of samples have machined surface roughness above 0.5 μm. Because most of the numerical values of machining accuracy are continuous and unique, and it is obviously unrealistic to directly predict the numerical values of machining accuracy, the present disclosure performs a discretization processing on the machining accuracy samples and converts the problem of predicting machining accuracy into the problem of predicting accuracy interval. 0.1 μm is taken as the discretized segment interval, and the number of samples larger than 0.5 μm are classified into one category. The relevant time domain and frequency domain signal features are extracted, and the signal feature matrix is constructed as the input of the prediction model.

The principal component analysis method is used for performing feature screening, and the signal features with strong correlation and low discrimination are removed. Finally, 18 signal features with the highest contribution rate are selected to construct a feature matrix. There are a total of 1000 groups of preprocessed sample data, including 900 groups of training sets and 100 groups of testing sets.

In step S2, the features corresponding to each key physical signal include time domain signal features and frequency domain signal features.

In step S3, respective signal feature matrixes are input into a machined surface roughness prediction model for training, and the trained machined surface roughness prediction model is obtained. Since the data scales of respective signals are different, in this embodiment, normalization processing is performed on the data, so as to achieve the effect of accelerating training. The current signal, the temperature signal and the vibration signal that are normalized are input into a convolution network model.

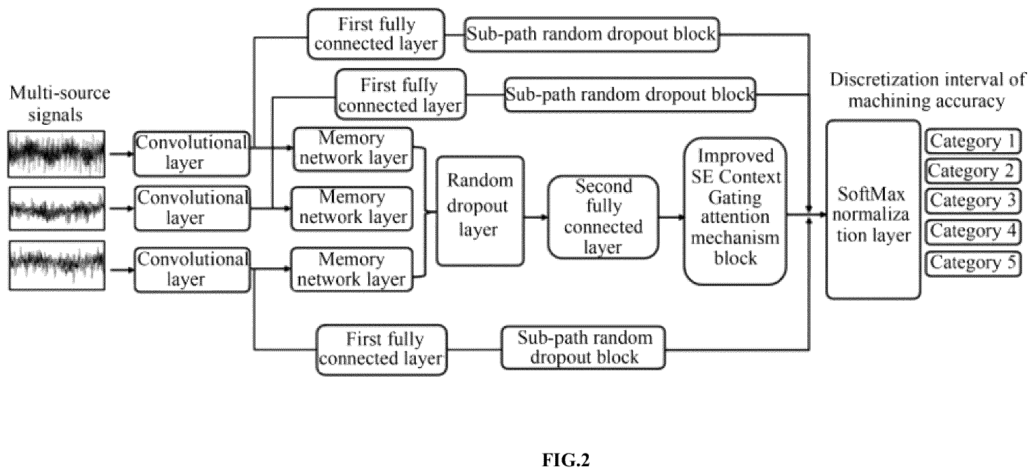

As shown in FIG. 2, the machined surface roughness prediction model includes a convolution layer, a memory network layer, a random dropout layer, a fully connected layer, a sub-path random dropout block, an improved SE Context Gating attention mechanism block and a classification module. The fully connected layer includes a first fully connected layer and a second fully connected layer.

Each of the signal feature matrixes is input into the corresponding convolution layer, an output of each convolution layer is input into the classification module after passing through a corresponding first fully connected layer and the sub-path random dropout block, outputs of all convolution layers are input into the random dropout layer after passing through a corresponding memory network layer, the random dropout layer is connected with the improved SE Context Gating attention mechanism block through a second fully connected layer, the improved SE Context Gating attention mechanism block is connected with the classification module, and the classification module outputs a prediction result of machined surface roughness. The convolution layer is used to compress the signal feature matrix. In order to reduce the loss of signal information, pooling processing is not performed during the convolution process of the convolutional layer, and only data compression is achieved. A long-term and short-term memory network layer is used for preliminary feature extraction. The random dropout layer is used to randomly discard some features, thereby avoiding the problem of over-fitting caused by too many neurons. The sub-path random dropout block is used to simulate the lack of some modes, so that the model is more robust. The improved SE Context Gating attention mechanism block is used to suppress the activation of signal features with a low contribution rate and perform feature fusion on the fused features again. On the basis of the attention mechanism SE structure, the present disclosure removes the first fully connected layer therein, that is, a fully connected layer is directly used to process the feature vector X in the attention channel. Assuming that the number of input signal channels is c, the feature vector of 1×1×c is obtained by using a sigmoid layer, which increases the parameter quantity of the module from c²/r to c while reserving more signal features. The classification module is the SoftMax normalization layer, which is used to output the prediction result of machined surface roughness. The distribution conditions of the prediction result of surface roughness in respective probability interval are obtained through the fully connected layer, and the final model prediction accuracy is 84%.

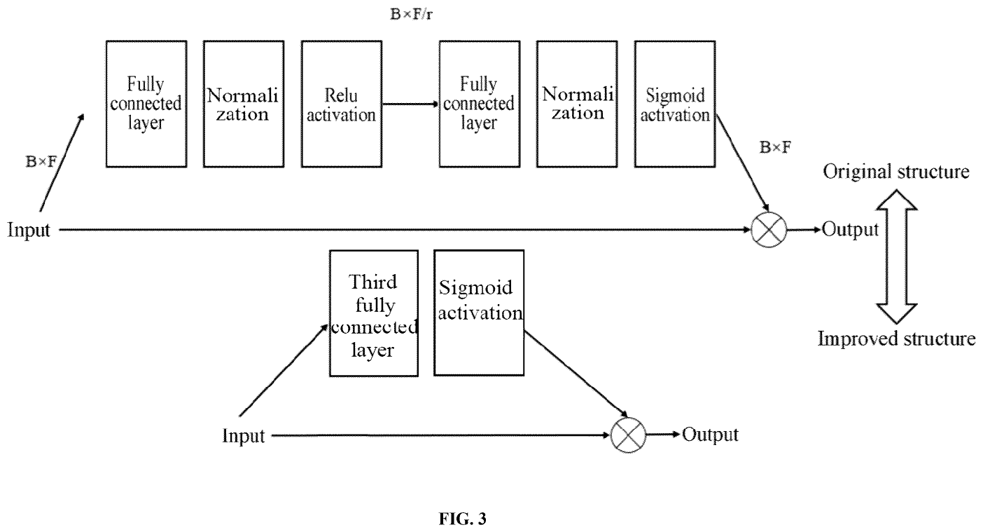

As shown in FIG. 3, the improved SE Context Gating attention mechanism block includes a third fully connected layer and an activation layer, an input of the improved SE Context Gating attention mechanism block is used as an input of the third fully connected layer, the third fully connected layer is connected with the activation layer, a fused feature after performing a feature fusion on an output of the activation layer and the input of the improved SE Context Gating attention mechanism block is used as an output of the improved SE Context Gating attention mechanism block. In FIG. 3, B (Batchsize) indicates the number of samples in each group, F indicates the feature dimension, and r indicates the compression ratio of the improved SE Context Gating attention mechanism block.

With the increase of service time of the grinding machine, the established machining accuracy prediction model will have performance degradation problems. By comparing the prediction conditions of the model after the experimental grinding machine has been in service for a long time, the machining accuracy prediction accuracy rate after a long time span from the initial training is only about 40%, which shows that the performance of the grinding machine degrades in a long time span.

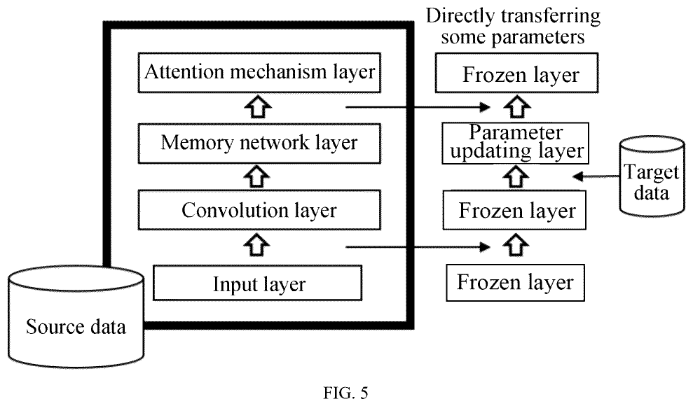

S4: a machine tool single-index degradation model is constructed according to the measured degradation data (the data is part of the existing degradation data of the current computer numerical control machine tool) of the computer numerical control machine tool to fit the nonlinear and non-Gaussian machine tool degradation system, thereby conforming to and tracking the degradation trend of the current computer numerical control machine tool. The degradation trend of the current computer numerical control machine tool and the timing of transfer learning are determined by using the machine tool single-index degradation model. In different degradation stages of the degradation trend, a network model transferring is performed on the trained machined surface roughness prediction models by using a transferring method subjected to network layered freezing training according to the key physical signals of respective degradation stages, so as to obtain the machined surface roughness prediction model in different degradation stages, thereby dealing with the problem of performance degradation of machine tool after long-term service and improving the accuracy of the built neural network prediction model. Specifically, as shown in FIG. 5, in the process of performing a network layered freezing transferring, it is necessary to set the transfer learning rate for each layer. Considering that the network model has a multi-layer structure, the shallower a network is, the more random the knowledge of the network is, and the requirements for re-learning and re-training are higher. Therefore, with the increase of network layers, the learning rate set during the corresponding transfer learning will decrease. The SGD optimization algorithm is used to update the parameters of transfer training. A part of the network layer is frozen, that is, the network parameters of the corresponding layer are directly transferred, and the unfrozen network layer is trained with the data after the degradation of machine tool performance. The deeper the network layer is, the lower the learning rate set during the corresponding transfer learning is. For example, the convolution layer and the memory layer are frozen, the learning rate of the convolution layer is set, the convolution layer is retrained, and then the memory layer and the SCG fully connected layer are frozen and retrained in sequence. The SGD optimization algorithm is used to update the transfer training parameters. In this embodiment, freezing training is performed on the different network layers. The learning rate change base is set to 10 times, where the learning rate of the convolution layer is 0.005, the learning rate of the memory network layer is 0.05, and the learning rate of the attention mechanism layer is 0.5. The accuracy rate of final transferring model prediction result is 76.8%, and the average offset distance is about 0.26.

In S4, a formula of the machine tool single-index degradation model is as follows:

$$Y ( t ) = {m}_{t} \cdot exp ( {n}_{t} , t ) + {ε}_{t}$$

$${m}_{t} = {m}_{t - 1} + N ( 0 , {σ}_{m}^{2} )$$

where Y(t) is a degradation performance of the machine tool at time t, mₜ is an initial performance level of the machine tool at time t, nₜ indicates a degradation rate of the machine tool at time t, εₜ is Gaussian white noise, N(0, σₘ²) indicates a normal distribution random variable with a mean value of 0 and a variance of σₘ², and the parameters of the observation equation serve as the system state reflecting the current degradation trend.

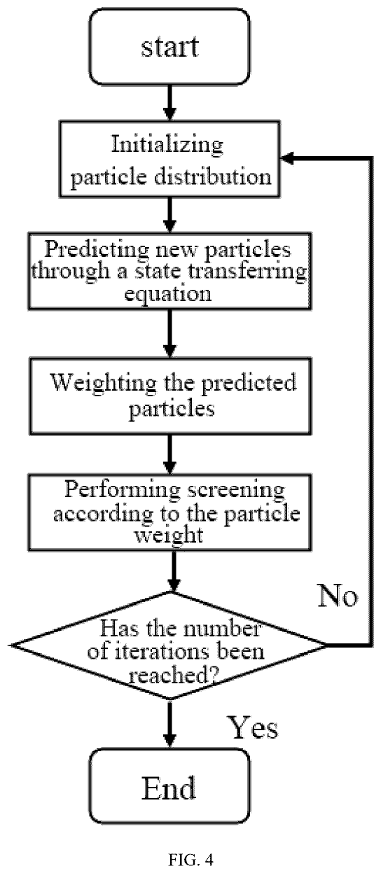

In S4, according to the measured degradation data of the current computer numerical control machine tool, as shown in FIG. 4, a Monte Carlo particle filter method is used to perform model update on a single-index degradation observation equation to obtain the machine tool single-index degradation model, so that the single-index degradation model can conform to and track the degradation trend of the current computer numerical control machine tool.

In S5: the degradation stage of the current computer numerical control machine tool is determined according to the machine tool single-index degradation model, and the machined surface roughness prediction model of the current degradation stage is selected, so as to obtain the corresponding surface roughness prediction result.

In this embodiment, vibration features, temperature signal features and current signal features are selected as the feature signals that affect the formation of surface roughness, according to the main physical factors that affect the roughness of grinding, and data information in the grinding process is acquired through a multi-factor sensor data acquisition method, and the data is preprocessed. The SE Context Gating attention mechanism is fused into the model training and improve the mechanism. The three original features extracted by the neural network are spliced in a dimension direction, and the spliced features are sent to the SE Context Gating attention mechanism to obtain a fusion result of the three features. By adding the fused features and the original features, it is possible to ensure that the original information of the original features is retained and that the information after the original features are fused is helpful for the prediction results. Through the fusion of multiple features, the model has the ability to learn the features of signals in the three modes separately and in fusion, so that the model can learn more feature information. For the problem that the prediction performance of the neural network degrades when the grinding machine is in long-term service, the accuracy of the built neural network prediction model is improved by using the transfer learning method based on the network layered freezing. Compared with the existing methods, the machining accuracy prediction model of the present disclosure can learn and fuse a plurality of signal features, and at the same time prevent the over-fitting problem of the prediction model, which is suitable for the result prediction in a long time span and provides a neural network model for the numerical control machining accuracy prediction of parts.

Finally, it should be explained that the above-mentioned embodiments and explanations are only used to illustrate the technical solution of the present disclosure and are not intended to limit the present disclosure. Those ordinarily skilled in the art should understand that the technical solution of the present disclosure can be modified or equivalently substituted without departing from the spirit and scope disclosed by technical solutions of the present disclosure, which should be included in the scope of protection of the claims of the present disclosure.

What is claimed is:

1. A method for predicting machined surface roughness of parts based on attention and transfer learning, comprising following steps of:
S1, acquiring key physical signals that affect evolution of machined surface roughness of parts from a computer numerical control machine tool;
S2, obtaining corresponding features, after performing a preprocessing and a feature extraction on respective key physical signals, and constructing corresponding signal feature matrixes according to the features corresponding to respective key physical signals;
S3, inputting respective signal feature matrixes into a machined surface roughness prediction model for training, and obtaining a trained machined surface roughness prediction model;
S4, constructing a machine tool single-index degradation model according to measured degradation data of the computer numerical control machine tool, determining a degradation trend of a current computer numerical control machine tool by using the machine tool single-index degradation model, and in different degradation stages of the degradation trend, performing network model transferring on the trained machined surface roughness prediction model by using a transferring method according to the key physical signals of respective degradation stages, so as to obtain machined surface roughness prediction models in different degradation stages; and
S5, determining a degradation stage of the current computer numerical control machine tool according to the machine tool single-index degradation model, and selecting a machined surface roughness prediction model of a current degradation stage, so as to obtain a corresponding surface roughness prediction result.

2. The method for predicting machined surface roughness of parts based on attention and transfer learning according to claim 1, wherein in the S2, a feature corresponding to each of key physical signals comprises a time domain signal feature and a frequency domain signal feature.

3. The method for predicting machined surface roughness of parts based on attention and transfer learning according to claim 1, wherein the machined surface roughness prediction model comprises a convolution layer, a memory network layer, a random dropout layer, a fully connected layer, a sub-path random dropout block, an improved SE Context Gating attention mechanism block and a classification module;
each of signal feature matrixes is input into the corresponding convolution layer, an output of each convolution layer is input into the classification module after passing through the corresponding first fully connected layer and the sub-path random dropout block, outputs of all convolution layers are input into the random dropout layer after passing through respective memory network layers, the random dropout layer is connected with the improved SE Context Gating attention mechanism block through a second fully connected layer, the improved SE Context Gating attention mechanism block is connected with the classification module, and the classification module outputs a prediction result of machined surface roughness.

4. The method for predicting machined surface roughness of parts based on attention and transfer learning according to claim 1, wherein the improved SE Context Gating attention mechanism block comprises a third fully connected layer and an activation layer, an input of the improved SE Context Gating attention mechanism block is used as an input of the third fully connected layer, the third fully connected layer is connected with the activation layer, a fused feature after performing feature fusion on an output of the activation layer and the input of the improved SE Context Gating attention mechanism block is used as an output of the improved SE Context Gating attention mechanism block.

5. The method for predicting machined surface roughness of parts based on attention and transfer learning according to claim 1, wherein in the S4, a formula of the machine tool single-index degradation model is as follows:
$$Y ( t ) = {m}_{t} \cdot exp ( {n}_{t} , t ) + {ε}_{t}$$
where Y(t) is a machine tool degradation performance at time t, mₜ is an initial machine tool performance level at time t, nₜ indicates a machine tool degradation rate at time t, and εₜ is Gaussian white noise.

6. The method for predicting machined surface roughness of parts based on attention and transfer learning according to claim 1, wherein in the S4, according to the measured degradation data of the current computer numerical control machine tool, a Monte Carlo particle filtering method is used to perform model update on a single-index degradation observation equation to obtain the machine tool single-index degradation model.
